(19) United States
(12) Patent Application Publication
(10) Pub. No.: US 2015/0309112 A1
(43) Pub. Date: Oct. 29, 2015

(54) THERMAL HEAD FOR DEVICE UNDER TEST AND METHOD FOR CONTROLLING THE TEMPERATURE OF DEVICE UNDER TEST

(71) Applicant: MARVELOUS TECHNOLOGY PTE LTD, Singapore (SG)

(72) Inventor: Yew Poh GOH, Singapore (SG)

(21) Appl. No.: 14/651,671

(22) PCT Filed: Dec. 12, 2012
(86) PCT No.: PCT/SG2012/000471

§ 371 Date: Jun. 12, 2015

(51) Int. Cl. G01R 31/28

(52) U.S. Cl. CPC G01R 31/2874

(57) ABSTRACT

A thermal head for device under test having a gimbal fixture and a protective casing and an air chamber having an air inlet hole and a plurality of O-ring grooves to form a pneumatic control mechanism, comprising (a) a cooling chamber within the protective casing having at least one inlet and at least one outlet formed on each of the opposite edge of the chamber for the flow of a cooling fluid from the inlet to the outlet to provide a cooling temperature to a device under test which comes into contact with the thermal head; (b) a metal plate being formed below the cooling chamber, wherein the metal plate touches the surface of the device under test when the thermal head is in operation; (c) an air gap formed between the cooling chamber and the metal plate, wherein the size of the gap depends on distance between the cooling chamber and the metal plate, wherein the cooling chamber moves relative to the metal plate; and (d) a pair of coil spring mechanism disposed in between the base of the metal plate and a jacket covered the cooling chamber at the opposite edges thereof. The present invention also relates to a method of controlling the temperature of a device under test.

### TECHNICAL FIELD

The present invention relates generally to the field of thermal control and/or conditioning of a device under test, such as microprocessor, undergoing electrical testing, or other devices that may be in use or undergoing testing. More particularly, the present invention relates to a thermal head used for heating/cooling microprocessor during industrial test conditions.

### BACKGROUND OF THE INVENTION

In the process of production of electronic devices, such as microprocessors (hereinafter also known as Devices Under Test (DUT), Water-based Thermal Solution which is known as thermal head is used to control the desired test temperature by way of an electric heater with or without a thermoelectric cooler for its dynamic sequence.

A heat sink is a component that transfers heat generated within a solid material to a fluid medium, such as air or liquid. Heat sink helps to cool electronic and optoelectronic devices such as CPU, high-power lasers, and Light-emitting diodes (LEDs). Thermoelectric cooling uses the Peltier effect to create a heat flux between the junctions of two different types of materials. A Peltier cooler, heater, or thermoelectric heat pump is a solid-state active heat pump which transfers heat from one side of the device to the other, with consumption of electrical, depending on the direction to the current. Such an instrument is called thermoelectric cooler (TEC).

An electric heater is an electrical appliance that converts electrical energy into heat. The heating element inside every electric heater is simply an electrical resistor, and works on the principle of Joule heating. An electric current though a resistor converts electrical energy into heat energy.

With increases in electronic circuit chip density for microprocessors, as measured in circuit's per unit area, there has also been produced a corresponding increase in thermal energy which must be removed from these devices particularly when they are run at ever increasing frequencies.

Accordingly, it seems that there is a significant problem in the removal of sufficient heat from microprocessors. Moreover, it is particularly desirable to be able to do this, as much as possible, without energy wastage but to maintain the desired set temperature conditions.

Conventional heat sinks, however, are limited in their capabilities even if one employs heat sinks with taller fin structures. Such heat sinks are limited because, with longer fins, the efficiency drops quickly because little heat reaches the fin tips. FIG. 1 schematically shows a tradition mechanical stack-up of water-based thermal head. It can be seen that these common assemblies of water-based thermal heads are maintaining constant mechanical contact with all major components of the thermal head and the device under test which allows heat removal to be constantly, which is shown in FIG. 2. The drawback of the constantly contact with the major components of the thermal head is that a waste of energy is occurred when the thermal head is used to test the device under test at a specific higher temperature as more energy is needed to use to cancel the cooler temperature of the cooling chamber.

U.S. Pat. No. 6,084,215 discloses a test apparatus which can test the chip still in a wafer state. A wafer temperature control apparatus is proposed which can accurately grasp and stabilize a test temperature during the reliability test of the chip still in the wafer state.

U.S. Pat. No. 8,040,145 discloses a temperature control device that includes a miniature fluid-cooled heat sink with integral heater and sensing elements. The device is used as part of a temperature control system to provide a controlled temperature surface to an electronic DUT, such as a semiconductor device, during the testing phase. The liquid-cooled heat sink includes two internal cooling passages with inlets, outlets and heat transfer portions. The heat transfer portions are located on separate planes and may include cooling fins. There are two integral heaters positioned in the device.

U.S. Pat. No. 7,639,029 discloses a heat sink pedestal device for use with a thermal unit comprising: an interposer, having a pedestal configured to contact a unit under test; an interface medium chamber, compressed between the interposer and the thermal unit, wherein an interface sealant defines a perimeter of the interface medium chamber; and a retainer, holding the interposer and mounted to the thermal unit, having a retainer opening for allowing the pedestal to extend through the retainer opening to contact the unit under test.

U.S. Pat. No. 6,489,793 discloses a system for controlling a temperature of a device under test, comprising: a measuring device for measuring an instantaneous power consumption by the device during testing; a heat exchanger in conductive contact with the device; and a thermal controller for controlling the heat exchanger by using the measured instantaneous power consumption by the device to regulate the temperature of the device during testing, wherein: the measuring device comprises: at least one current measuring device for monitoring the current supplied to the device by one or more power supplies; at least one voltage measuring device for monitoring the voltage supplied to the device by one or more power supplies; and a monitoring circuit, coupled to the at least one current measuring device and to the at least one voltage measuring device, for producing a power usage signal from the monitored current and voltage; and the thermal controller for determining a setting of the heat exchanger comprises a thermal control circuit which utilizes the following equation for estimating the temperature of the device.

U.S. Pat. No. 6,886,976 discloses a method of controlling temperature of an electronic component under test, the method comprising the steps of: (a) obtaining a temperature control apparatus comprising: a heater assembly configured to provide a first thermal path to a device under test; and a heat sink configured to provide a second thermal path to said device under test, said first and second thermal paths corresponding to parallel thermal resistances associated with said device under test; wherein said heater assembly comprises a heating surface and said heat sink comprises a cooling surface that is coplanar with, and physically distinct from, said heating surface; (b) applying the cooling surface to a first portion of said device under test; and (c) concurrently applying the heating surface to a second portion of said device under test in response to a test temperature setting.

U.S. Pat. No. 6,717,115 entitled “Semiconductor Handler For Rapid Testing” discloses a semiconductor handling system having a thermal plate comprising: a) a first member having a plurality of holes therethrough; b) a second member adjacent the first member having vacuum channels formed therethrough, the vacuum channels connected to the holes; c) an electrical resistance heater embedded in the thermal plate; and d) a fluid passage, having fluid inlet and a fluid outlet, formed by a channel in a surface of at least one of the first member or the second member.

### BRIEF SUMMARY OF THE INVENTION

The thermal head for device under test of the present invention provides isolation to the specific heating and cooling zones of the thermal head in testing a device under test so as to significantly reduce energy wastage in the course of maintaining temperature conditions by way of eliminating constant heat transfer as a result of mechanical contact of the heating and cooling zone found in conventional thermal heads.

A main object of the present invention is to provide a thermal head for device under test, wherein the cooling chamber of the thermal head is fluid-cooled by employing chilled stream of fluids such as chilled water, air, Freon and other cooling agents. The dissipate power is up to 1000W while the devices' temperature is ranging between −50 to 200 deg C., preferably −10 to 120 deg C.

Another object of the present invention is to provide a thermal head for device under test, wherein the thermal head is cost effective as the consumption of the electricity is greatly reduced by eliminating the use of thermoelectric cooler while maintaining high thermal capability.

The object of the present invention is to provide a thermal head for device under test having a gimbal fixture and a protective casing and an air chamber having an air inlet hole and a plurality of O-ring grooves to provide a pneumatic control mechanism, comprising

(a) a cooling chamber within the protective casing having at least one inlet and at least one outlet formed on each of the opposite edge of the chamber for the flow of a cooling fluid from the inlet to the outlet to provide a cooling temperature to a device under test which comes into contact with the thermal head;

(b) a metal plate with an embedded heater being formed below the cooling chamber, wherein the metal plate touches the surface of the device under test when the thermal head is in operation;

(c) an air gap formed between the cooling chamber and the metal plate, wherein the size of the gap depends on distance between the cooling chamber and the metal plate, wherein the cooling chamber moves relative to the metal plate;

(d) a pair of coil spring mechanism disposed in between the base of the metal plate and a jacket cover for the cooling chamber at the opposite edge thereof to provide upward disengagement of the cooling chamber to form a gap when cooling is not needed; and wherein the linear downward movement of the cooling chamber is activated by the pneumatic control mechanism; and wherein the temperature of the device under test or the thermal response time of the test temperature of the device under test being placed directly beneath the metal plate is controlled by either heating up the device under test by the heater embedded in the metal plate or the device under test is cooled when the cooling chamber is in operation and is in contact with the metal plate.

Yet another object of the present invention is to provide a head for device under test having a gimbal fixture and a protective casing and an air chamber having an air inlet hole and a plurality of O-ring grooves to provide a pneumatic control mechanism, comprising

(a) a cooling chamber within the protective casing having at least one inlet and at least one outlet formed on each of the opposite edge of the chamber for the flow of a cooling fluid from the inlet to the outlet to provide a cooling temperature to a device under test which comes into contact with the thermal head;

(b) a metal plate with an embedded heater being formed below the cooling chamber, wherein the metal plate touches the surface of the device under test when the thermal head is in operation;

(c) an air gap formed between the cooling chamber and the metal plate, wherein the size of the gap depends on distance between the cooling chamber and the metal plate, wherein the cooling chamber moves relative to the metal plate;

(d) a pair of coil spring mechanism disposed in between the base of the metal plate and a jacket cover for the cooling chamber at the opposite edge thereof to provide upward disengagement of the cooling chamber to form a gap when cooling is not needed;

(e) a fin array being formed on the surface of the heat plate facing the cooling chamber; and wherein the linear downward movement of the cooling chamber is activated by the pneumatic control mechanism; and wherein the temperature of the device under test or the thermal response time of the test temperature of the device under test being placed directly beneath the metal plate is controlled by either heating up the device under test by the heater embedded in the metal plate or the device under test is cooled when the cooling chamber is in operation and is in contact with the metal plate.

A further object of the present invention is to provide a method for controlling the temperature of a device under test using the thermal head to a cooler temperature for the device under test, comprising the steps of

(i) placing the thermal head on the surface of the device under test so that the metal place of the thermal head is fully in contact with the device under test;

(ii) moving the cooling chamber of the thermal head towards the heated metal plate of the thermal head until the cooling chamber is in full contact with the metal plate to dissipate heat away from the hot device under test;

(iii) passing a cooling fluid through the inlet at one edge of the cooling chamber and letting out the cooling fluid from the outlet of the cooling chamber so that the heat generated from the device under test is carried away by the cooling fluid.

Still a further object of the present invention is to provide method for controlling the temperature of a device under test using the thermal head set to heat up the device under test, comprising the steps of

(i) moving the cooling chamber of the thermal head away from the heated metal plate of the thermal head until a sizeable gap is formed between the cooling chamber and the metal plate while the metal plate is fully in contact with the device under test;

(ii) stopping passing a cooling fluid through the inlet at one edge of the cooling chamber to the cooling chamber;

(iii) heating the metal plate with the embedded heater of the metal plate until the desirable temperature of the device under test is obtained.

A further object of the present invention is to provide a thermal head for device under test, wherein the range of the temperature that the thermal head can achieve is from −50 deg C. to 200 deg C.

According to certain aspects of the present invention, several advantages are realized. One advantage is that the thermal head of the present invention allows the operators to achieve operating targets and/or conditions faster than the traditional thermal heads, and thus, lesser wastage of energy as the operating time and conditions are met within a shorter time and with less energy usage.

### BRIEF DESCRIPTION OF THE DRAWING

The invention will become more fully understood from the detailed description given below for illustration only, and thus are not limitative of the present invention, and wherein

FIG. 1 is a schematic view of a conventional thermal head assembly wherein the cooling chamber maintains constant mechanical contact with other major components of the thermal head, such as thermal electric cooler and/or the heat plate.

FIG. 2 is a schematic view showing constant heat removal of the conventional thermal head assembly.

FIG. 3 is a schematic view of a thermal head assembly in accordance with the present invention, wherein a gap is being formed between a cooling chamber and the metal plate in accordance with the present invention.

FIG. 4 is a schematic view illustrating thermal impedance in accordance with the stack-up as shown in FIG. 3, wherein the heat transfer is restricted by an air gap.

FIG. 5 is a perspective view of a thermal head in accordance with the present invention.

FIG. 6 is a schematic rear view of the heat sink in accordance with the present invention.

FIG. 7 shows the pneumatic with spring mechanism of the thermal head in one preferred embodiment of the present invention.

FIG. 8 is a perspective view of the thermal head having the top fixture and the mounting poles in accordance with the present invention.

### DETAILED DESCRIPTION OF THE INVENTION

With reference to the figures, exemplary embodiments of the invention will now be described. However, it should be noted that, though the present invention describes various inventions or improvements that may be used in a heat sink system, these improvements may be used individually in a single application or various combinations, including all versions at once, may be used together. Towards this end, the exemplary embodiments discussed herein should not be viewed as individual inventions since they can be used collectively as well.

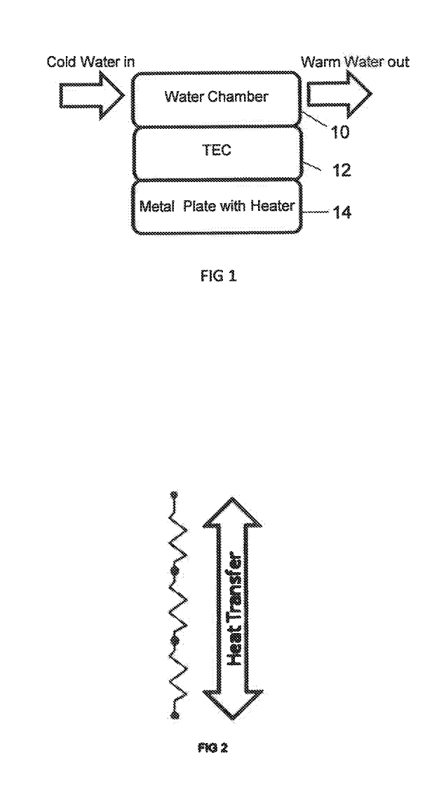

FIG. 1 illustrates a typical thermal head that is currently used in devices under test. Thermal head is a component of a metrological device created for test/validation of a processor.

Traditionally, all components of the thermal head are permanently stacked together regardless of test conditions. The conventional thermal head comprises a water chamber or the like (10), a thermoelectric cooler (12) and a heat plate with embedded electric heater (14). Such a conventionally mechanical stack-up of components allows heat transfer to occur constantly and hence results in energy wastage to maintain the desired set temperature conditions. For instance, if a device under test such as a microprocessor to be tested under a cooler temperature, more energy is used to reduce the temperature of the microprocessor to a desired temperature as heat energy from the heat plate will be conducted to the water chamber.

FIG. 2 depicts the constant heat transfer from the heat plate via the thermoelectric cooler (12) to the water chamber (10) where the heat is dissipated by stream of cold water passing through the chamber (10). If the microprocessor is to be heated up to a certain temperature, a part of heat energy from the heater will transfer to the water chamber (10) via conduction even the flowing of cold water to the water chamber (10) is cut off.

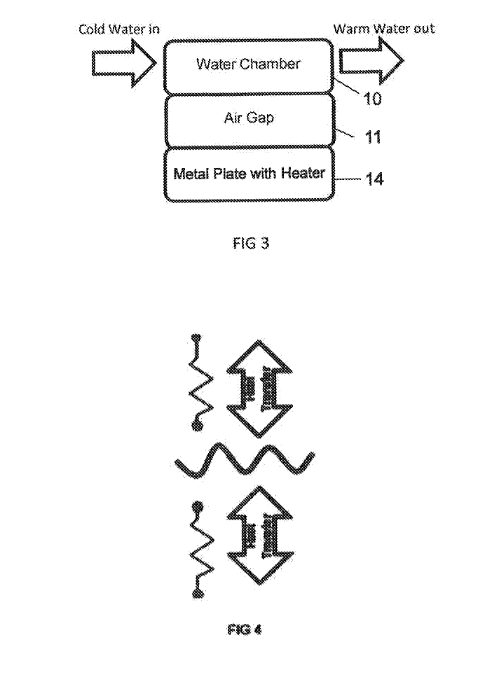

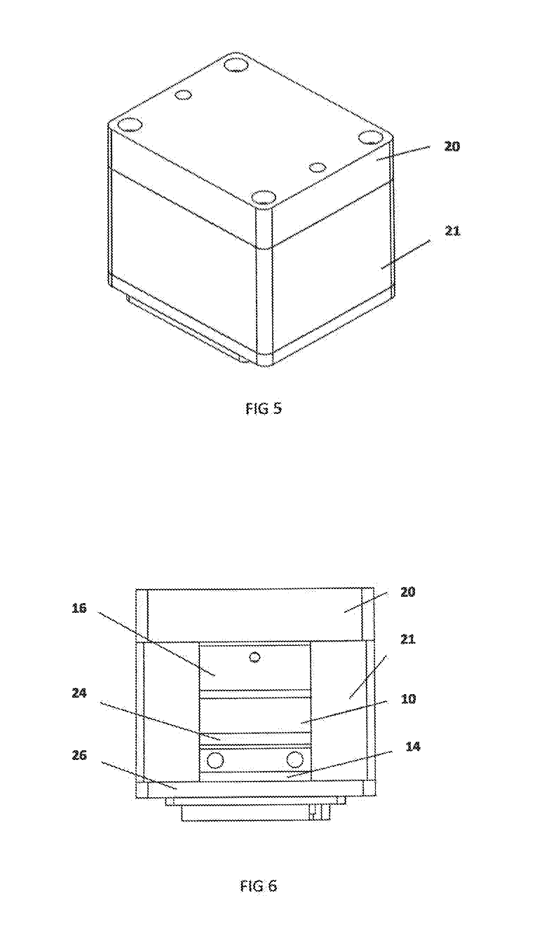

FIG. 3 schematically depicts a thermal head system in accordance with the present invention. In accordance with the present invention, the thermal head for device under test having a gimbal fixture (20) (shown in FIG. 6) and a protective casing (21) comprises (a) a cooling chamber (10) within the protective casing (21) having at least one inlet and at least one outlet formed on each of the opposite edge of the cooling chamber (10) for the flow of a cooling fluid such as chilled water or chilled air, Freon and other cooling agents from the inlet to the outlet to provide a cooling temperature to a device under test which comes into contact with the thermal head;

(b) a metal plate (14) with an embedded heater positioned below the cooling chamber (10), wherein the metal plate (14) touches the surface of the device under test when the thermal head is in operation;

(c) an air gap (11) formed between the cooling chamber (10) and the metal plate (14), wherein the size of the gap (11) depends on distance between the cooling chamber (10) and the metal plate (14), wherein the cooling chamber (10) moves relative to the metal plate (14) ; and wherein the temperature of the device under test or the thermal response time of the test temperature of the device under test being placed directly beneath the metal plate (14) is controlled by either heating up the device under test by the heater embedded in the metal plate (14) or the device under test is cooled when the cooling chamber (10) is in operation and is moved to in contact with the metal plate (14). In accordance with the present invention, depending on testing requirements for the device under test, it is not always need the heater in the metal plate 14. The plate 14 can be without heater, as heat is generated by the device under test.

In accordance with the present invention, a pneumatic mechanism comprising an air chamber (16), an air inlet hole (27) and a plurality of O-ring grooves (29) is designed to cause the linear downward movement of the cooling chamber (10) to touch the surface of the metal plate (14). Thus the heat of the microprocessor is dissipated or the microprocessor is cooled to a desired temperature.

A pair of coil spring mechanism (28) are disposed in between an ejector base (26) and a jacket cover for the cooling chamber (10) at the opposite edge thereof to provide upward disengagement of the cooling chamber (10) to form the gap (11) when cooling is not needed.

In another preferred embodiment of the present invention, the thermal head further comprises a fin array (24) which is a separate piece from heat plate. The fin array (24) is a combined piece to water chamber (10). The fin array (24) increases the heat transfer area of the metal plate (14) as the fin array (24) is provided with a plurality of protrusions blocks which facilitate the increase of surface contact area with the cooling chamber (10).

All these components are enclosed within a gimbal fixture (20) (shown in FIG. 6) having the ejector base (26) and supported by a plurality of mounting poles (30) (shown in FIG. 8), wherein the mounting poles (30) are respectively disposed at the corners of the base (26).

In accordance with the present invention, a thermoelectric cooler which is employed in conventional thermal head is not required, instead, an air gap (11) is provided and is positioned between the cooling chamber (10) and the heat plate with embedded heater (14). The air gap (11) restricts heat removal by way of conduction between the cooling chamber (10) and the metal plate (14).

The prevention of heat from the metal plate (14) by the gap (11) is required if the device under test is to be carried out at a higher temperature. In other words, the heat generated by the microprocessor is retained and heat energy thus needed from the metal plate (14) heated by the embedded heater is lesser.

In the present invention, the cooling and heating requirement of the heat plate (14) is controlled by computer software.

Referring to FIGS. 5 and 6, there is shown the thermal head comprises the gimbal fixture (20) which is a two-pieces rectangular metal plate assembly forming the rigid structure for the thermal head, a protective casing (21), an air chamber (16), a cooling chamber (10), a fin array (24), a metal plate with embedded heater (14) and an ejector base (26). The gimbal fixture (20) is springs loaded metal plate assembly and the protective casing 21 is a plate like structure to enclose the thermal head assembly in accordance with the present invention. The metal plate (14) with embedded heater is a medium which absorbs heat generated by the device under test, for instance, the microprocessor, and the heat is then transferred to the fin array (24) to be dissipated into the surrounding.

In accordance with the present invention, the fin array (24) is plate-like structure having a plurality of miniature protrusion blocks (not shown) to increase the surface contact area having constant flow of chilled water and it also provides improved heat transfer through conduction and convention to achieve the goal of maximum efficiency of heat removal from the device under test.

The present invention also discloses a method for controlling the temperature of a device under test using the thermal of which the structure is mentioned above to a cooler temperature for the device under test. The method comprises the steps of

(i) placing the thermal head on the surface of the device under test so that the metal plate (14) of the thermal head is fully in contact with the device under test;

(ii) moving the cooling chamber (10) of the thermal head towards the heated metal plate (14) of the thermal head until the cooling chamber (10) is in full in contact with the metal plate (14) to dissipate heat away from the hot device under test;

(iii) passing a cooling fluid such as chilled water, chilled air, Freon, and/or other agents through the inlet at one edge of the cooling chamber (10) and letting out the cooling fluid from the outlet of the cooling chamber (10) so that the heat generated from the device under test is carried away by the cooling fluid. Thus the microprocessor or the device under test is cooled.

When the device under test is to be tested at a higher temperature, in accordance with the present invention, the method comprises the steps of (i)moving the cooling chamber (10) of the thermal head away from the heated metal plate (14) of the thermal head until a sizeable gap (11) is formed between the cooling chamber (10) and the metal plate (14) while the metal plate (14) is fully in contact with the device under test; (ii) stopping passing a cooling fluid through the inlet at one edge of the cooling chamber (10) to the cooling chamber (10); and (iii) heating the metal plate (14) with the embedded heater of the metal plate (14) until the desirable temperature of the device under test is obtained. As mentioned earlier, the linear downward movement of the cooling chamber (10) of the thermal head is attained by the pneumatic mechanism and the upward movement by the disengagement of the cooling chamber (10) is achieved by the spring mechanism.

The range of temperature attained by the thermal head of the present invention is from −50 to 200 deg C.

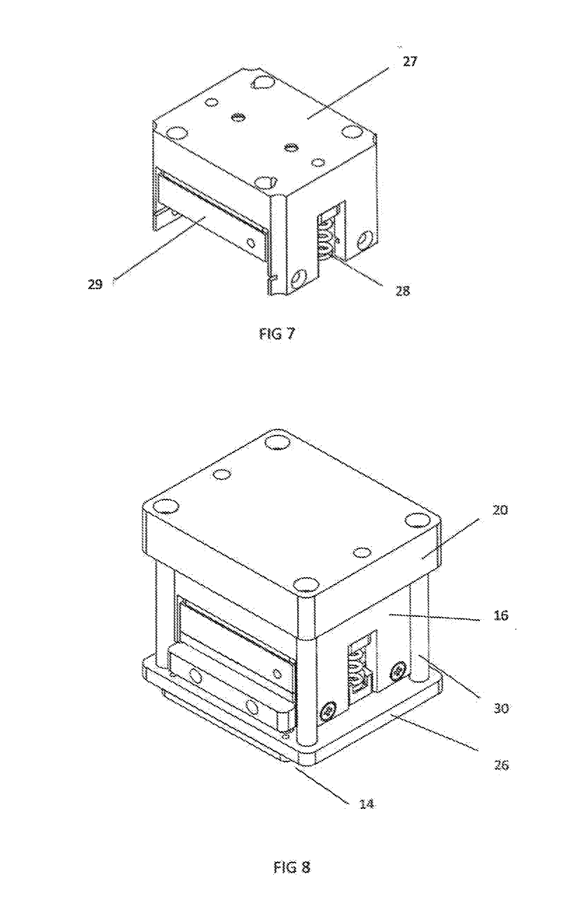

FIG. 7 shows schematically the thermal head in accordance with the present invention. As shown in the figure, the air chamber (16) and the cooling chamber (10) together with the air inlet hole (27) and O-ring groove (29) provide the linear downward movement of the cooling chamber (10) to the surface of the metal plate (14) to provide heat removal from the device under test. In other words, the downward movement of the cooling chamber (10) is activated by means of the pneumatic mechanism or the like. In the present invention, the downward movement of the cooling chamber (10) causes the mating of the chamber with the top surface of the metal plate (14) which functions to remove heat generated from devices under test. Referring again to FIG. 7, a pair of coil spring mechanism (28) provides upward disengagement mechanical action so as to create an air gap (11) between the cooling chamber (10) and the metal plate (14) when cooling function of the device under test is not required.

FIG. 8 shows the base (26) being affixed to the gimbal fixture (20) by means of a plurality of extending mounting poles (30). In accordance with the present invention, four mounting poles (20) are respectively positioned vertically at the respective corners of the base (26) and the gimbal fixture (20). A plurality of plungers are fixed to the base (26) so as to separate the metal plate (14) from the device under test, such as the microprocessor, during removal of the thermal head.

As mentioned earlier, the present invention allows the device under test to be tested in a temperature range of −50° C. to 200° C., and that in the presence of the gap (11) between the cooling chamber (10) and the metal plate (14), the thermal head is able to achieve operating targets or conditions faster than conventional thermal heads. In other words, the thermal response is short if the thermal head of the present invention is employed. This leads to energy savings as operating time and operating conditions are met within a very short period and with lesser energy.

While the invention has been described in what is presently considered to be a preferred embodiment, many variations and modifications will become apparent to those skilled in the art. Accordingly, it is intended that the invention not be limited to the specific illustrative embodiment but be interpreted within the full spirit and scope of the appended claims.

1. A thermal head for device under test having a gimbal fixture and a protective casing and an air chamber having an air inlet hole and a plurality of O-ring grooves to form a pneumatic control mechanism, comprising;
(a) a cooling chamber within the protective casing having at least one inlet and at least one outlet formed on each of the opposite edge of the chamber for the flow of a cooling fluid from the inlet to the outlet to provide a cooling temperature to a device under test which comes into contact with the thermal head;
(b) a metal plate formed below the cooling chamber, wherein the metal plate touches the surface of the device under test when the thermal head is in operation;
(c) an air gap formed between the cooling chamber and the metal plate, wherein the size of the gap depends on distance between the cooling chamber and the metal plate, wherein the cooling chamber moves relative to the metal plate; and
(d) a pair of coil spring mechanism disposed in between the base of the metal plate and a jacket covered the cooling chamber at the opposite edges thereof;
wherein the linear downward movement of the cooling chamber is activated by the pneumatic control mechanism; and wherein the temperature of the device under test or the thermal response time of the test temperature of the device under test being placed directly beneath the metal plate is controlled by either heating up the device under test by the device itself or the device under test is cooled when the cooling chamber is in operation and is moved to in contact with the metal plate.

2. A thermal head for device under test having a gimbal fixture and a protective casing and an air chamber having an air inlet hole and a plurality of O-ring grooves to form a pneumatic control mechanism, comprising
(a) a cooling chamber within the protective casing, mounted with a plurality of O-ring grooves, having at least one inlet and at least one out let formed on each of the opposite edge of the chamber for the flow of a cooling fluid from the inlet to the outlet to provide a cooling temperature to a device under test which comes into contact with the thermal head;
(b) a metal plate formed below the cooling chamber, wherein the metal plate touches the surface of the device under test when the thermal head is in operation;
(c) an air gap formed between the cooling chamber and the metal plate, wherein the size of the gap depends on distance between the cooling chamber and the metal plate, wherein the cooling chamber moves relative to the metal plate;
(d) a pair of coil spring mechanism disposed in between the base of the metal plate and a jacket covered the cooling chamber at the opposite edges thereof; and
(e) a fin array being a separate piece combined piece to the water chamber (10); and
wherein the linear downward movement of the cooling chamber is activated by the pneumatic control mechanism; and wherein the temperature of the device under test or the thermal response time of the test temperature of the device under test being placed directly beneath the metal plate is controlled by either heating up the device under test by the heater embedded in the metal plate or the device under test is cooled when the cooling chamber is in operation and is moved to in contact with the metal plate.

3. The thermal head of claim 2, wherein the fin array is provided with a plurality of protrusions blocks to increase surface contact area with the cooling chamber.

4. The thermal head of claim 1 or 2, further comprising a plurality of miniature plungers in the base of the thermal head so as to separate the heat plate from the device under test when the thermal head is removed.

5. The thermal head of claim 1, wherein the cooling chamber is moveably mounted to the gimbal fixture allowing the cooling chamber to move downward to contact with the metal plate of the thermal head to cool the metal plate.

6. The thermal head of claim 1 or 5, wherein the cooling chamber moves away from the metal plate if the metal plate is to be heated by the embedded heater.

7. The thermal head of claim 1 or 2, wherein the metal plate is provided with an embedded heater.

8. A thermal head for device under test having a gimbal fixture and a protective casing and an air chamber having an air inlet hole and a plurality of O-ring grooves to form a pneumatic control mechanism, characterized in that an air gap is formed between the cooling chamber and the metal plate for used as a mean of insulation to improve efficiency of both heating and cooling processes of the thermal head.

9. A method for controlling the temperature of a device under test using the thermal head for device under test having a gimbal fixture and a protective casing and an air chamber having an air inlet hole and a plurality of O-ring grooves to form a pneumatic control mechanism to a cooler temperature for the device under test, comprising the steps of
(i) placing the thermal head on the surface of the device under test so that the metal plate of the thermal head is fully in contact with the device under test;
(ii) moving the cooling chamber of the thermal head towards the heated metal plate of the thermal head until the cooling chamber is in full contact with the metal plate to dissipate heat away from the hot device under test;
(iii) passing a cooling fluid through the inlet at one edge of the cooling chamber and letting out the cooling fluid from the outlet of the cooling chamber so that the heat generated from the device under test is carried away by the cooling fluid.

10. A method for controlling the temperature of a device under test using the thermal head for device under test having a gimbal fixture and a protective casing and an air chamber having an air inlet hole and a plurality of O-ring grooves to form a pneumatic control mechanism to heat up the device under test, comprising the steps of
(i) moving the cooling chamber of the thermal head away from the heated metal plate of the thermal head until a sizeable gap is formed between the cooling chamber and the metal plate while the metal plate is fully in contact with the device under test;
(ii) stopping passing a cooling fluid through the inlet at one edge of the cooling chamber to the cooling chamber; and
(iii) heating the metal plate with the embedded heater of the metal plate until the desirable temperature of the device under test is obtained.

11. The thermal head of claim 9 or 10, wherein the moving of the cooling chamber downward to the metal plate is by way of the pneumatic mechanism formed by the air chamber, the air inlet hole and a plurality of O-grooves and the disengagement of the heat plate with the cooling chamber is by way of the spring mechanism.

12. The thermal head of claim 1 or 2, wherein the cooling fluid is selected from the group consisting of chilled water, Freon, or chilled air.

13. The method for controlling the temperature of a device under test of claim 9 or 10, wherein the cooling fluid is selected from the group consisting of chilled water, Freon, or chilled air.

14. A thermal head for device under test having a gimbal fixture and a protective casing
(a) a cooling chamber within the protective casing having at least one inlet and at least one outlet formed on each of the opposite edge of the chamber for the flow of a cooling fluid from the inlet to the outlet to provide a cooling temperature to a device under test which comes into contact with the thermal head;
(b) a metal plate with an embedded heater being formed below the cooling chamber, wherein the metal plate touches the surface of the device under test when the thermal head is in operation;
(c) an air gap formed between the cooling chamber and the metal plate, wherein the size of the gap depends on distance between the cooling chamber and the metal plate, wherein the cooling chamber moves relative to the metal plate;
wherein the cooling chamber is moveable downward or upward to the metal plate by means of a pneumatic control or a magnetic control and the temperature of the device under test or the thermal response time of the test temperature of the device under test being placed directly beneath the metal plate is controlled by either heating up the device under test by the heater embedded in the metal plate or the device under test is cooled when the cooling chamber is in operation and is moved to in contact with the metal plate.
